(19) United States
(12) Patent Application Publication
(10) Pub. No.: US 2024/0096747 A1
(43) Pub. Date: Mar. 21, 2024

(54) POWER MODULE THERMAL MANAGEMENT SYSTEM

(71) Applicant: PC KRAUSE AND ASSOCIATES, INC., West Lafayette, IN (US)

(72) Inventors: Jason WELLS, West Lafayette, IN (US); Nicholas BENAVIDES, West Lafayette, IN (US); Kevin MCCARTHY, West Lafayette, IN (US)

(21) Appl. No.: 18/368,902

(22) Filed: Sep. 15, 2023

Related U.S. Application Data
(60) Provisional application No. 63/407,249, filed on Sep. 16, 2022.

(51) Int. Cl. H01L 23/473; H01L 23/367; H05K 7/20

(52) U.S. Cl. CPC H01L 23/473; H01L 23/367; H05K 7/20945

(57) ABSTRACT

A thermal management system includes a baseplate assembly and a flow system. The baseplate assembly includes a baseplate and a semiconductor die arranged on the baseplate. The flow system includes a first flow path extending over and in thermal contact with the semiconductor die and a second flow path in thermal contact with the baseplate, the flow system including a fluid flowing through the first flow path and the second flow path. The flow system is configured to direct the fluid over the semiconductor die via the first flow path and to the baseplate via the second flow path so as to transfer heat away from the semiconductor die and from the baseplate so as to cool the baseplate assembly.

### CROSS-REFERENCE TO RELATED APPLICATIONS

This non-provisional application claims the benefit and priority, under 35 U.S.C. § 119(e) and any other applicable laws and statutes, to U.S. Provisional Application Ser. No. 63/407,249 filed on Sep. 16, 2022, the entire disclosure of which is incorporated herein by reference.

### BACKGROUND

The present disclosure relates to electronic systems, in particular electronic systems having more power dense solutions and improving the operation of such systems.

### SUMMARY

According to the present disclosure, a thermal management system includes a baseplate assembly including a baseplate defining an upper baseplate surface and a semiconductor die defining an upper semiconductor surface, the semiconductor die being arranged on the baseplate, and a flow system including a first flow path extending over and in thermal contact with the semiconductor die and a second flow path in thermal contact with the baseplate, the flow system including a fluid flowing through the first flow path and the second flow path. In some embodiments, the flow system is configured to direct the fluid over the semiconductor die via the first flow path and to the baseplate via the second flow path so as to transfer heat away from the semiconductor die and from the baseplate so as to cool the baseplate assembly.

In some embodiments, the first flow path is defined by at least one surface inlet channel that directs the fluid onto the semiconductor die and at least one surface outlet channel that receives the fluid from the semiconductor die and directs the fluid away from the semiconductor die.

In some embodiments, the second flow path is defined by at least one baseplate inlet channel that directs the fluid into thermal contact with the baseplate, at least one baseplate cooling channel that directs the fluid over or through the baseplate, and at least one baseplate outlet channel that receives the fluid from the at least one baseplates cooling channel and directs the fluid away from the baseplate.

In some embodiments, the flow system further includes a common surface outlet channel fluidically connected to the at least one surface outlet channel and to the at least one baseplate inlet channel such that the fluid is configured to flow from the at least one surface outlet channel to the at least one baseplate inlet channel so as to define a single continuous flow path from the first flow path to the second flow path.

In some embodiments, the flow system is configured to control a flow of the fluid over the semiconductor die such that, in a first operational mode, the fluid flows continuously and unimpeded over the upper semiconductor surface. In some embodiments, the flow system is configured to control a flow of the fluid over the semiconductor die such that, in a second operational mode, the fluid is directed onto the upper semiconductor surface and then remains on the upper semiconductor surface for a predetermined period of time such that the fluid boils.

In some embodiments, the flow system further includes at least one heat transfer enhancement arranged on the upper semiconductor surface, wherein the at least one heat transfer enhancement includes at least one of microchannels, a porous foam material, or a pin fin array, and wherein the at least one surface inlet channel directs the fluid through the at least one heat transfer enhancement.

In some embodiments, the baseplate is a low thermal impedance baseplate and the fluid is a dielectric refrigerant. In some embodiments, the semiconductor die is a field effect transistor die and is directly exposed to the fluid. In some embodiments, the fluid is a hydrofluorocarbon refrigerant.

In some embodiments, the fluid includes a first fluid and a second fluid, the flow system further includes a surface inlet supply channel configured to supply the first fluid to the first flow path and a baseplate inlet supply channel configured to supply the second fluid to the second flow path, and the first flow path is not in fluidic communication with the second flow path. In some embodiments, the first fluid is different than the second fluid.

According to a further aspect of the present disclosure, a thermal management system includes a baseplate assembly including a baseplate and a semiconductor die and a flow system in thermal contact with the baseplate and the semiconductor die and including a fluid configured to flow through the flow system. The flow system is configured to direct the fluid over the semiconductor die and to the baseplate so as to transfer heat away from the semiconductor die and from the baseplate so as to cool the baseplate assembly.

In some embodiments, the baseplate is a low thermal impedance baseplate. In some embodiments, the fluid is a dielectric refrigerant.

In some embodiments, the flow system includes a single continuous flow path that extends over and is in thermal contact with the semiconductor die and that is in thermal contact with the low thermal impedance baseplate.

In some embodiments, the flow system has at least two flow paths, the at least two flow paths including a first flow path that extends over and is in thermal contact with the semiconductor die and a second flow path that is in thermal contact with the low thermal impedance baseplate.

In some embodiments, the fluid includes a first fluid flowing through the first flow path and a second fluid flowing through the second flow path, and wherein the first fluid is different than the second fluid.

According to a further aspect of the present disclosure, a method includes providing a baseplate assembly including a baseplate defining an upper baseplate surface and a semiconductor die defining an upper semiconductor surface, arranging the semiconductor die on the baseplate such that the upper semiconductor surface is spaced apart from the upper baseplate surface, providing a flow system including a first flow path extending over and in thermal contact with the semiconductor die and a second flow path in thermal contact with the baseplate, the flow system including a fluid flowing through the first flow path and the second flow path, and directing the fluid over the semiconductor die via the first flow path and to the baseplate via the second flow path so as to transfer heat away from the semiconductor die and from the baseplate so as to cool the baseplate assembly.

In some embodiments, the first flow path is defined by at least one surface inlet channel that directs the fluid onto the semiconductor die and at least one surface outlet channel that receives the fluid from the semiconductor die and directs the fluid away from the semiconductor die. The second flow path is defined by at least one baseplate inlet channel that directs the fluid into thermal contact with the baseplate, at least one baseplate cooling channel that directs the fluid over or through the baseplate, and at least one baseplate outlet channel that receives the fluid from the at least one baseplates cooling channel and directs the fluid away from the baseplate. The flow system further includes a common surface outlet channel fluidically connected to the at least one surface outlet channel and to the at least one baseplate inlet channel such that the fluid is configured to flow from the at least one surface outlet channel to the at least one baseplate inlet channel so as to define a single continuous flow path from the first flow path to the second flow path.

Additional features of the present disclosure will become apparent to those skilled in the art upon consideration of illustrative embodiments exemplifying the best mode of carrying out the disclosure as presently perceived.

### BRIEF DESCRIPTION OF THE DRAWINGS

FIG. 1 is a perspective view of a thermal management system including a baseplate assembly and flow system according to the present disclosure;

FIG. 2 is a schematic view of the thermal management system of FIG. 1;

FIG. 3A is a perspective view of an exemplary heat transfer enhancement of the baseplate or the semiconductor die of the baseplate assembly of FIGS. 1 and 2, the heat transfer enhancement having elongated fins;

FIG. 3B is a perspective view of another exemplary heat transfer enhancement of the baseplate or the semiconductor die of the baseplate assembly of FIGS. 1 and 2, the heat transfer enhancement having narrow pins;

FIG. 3C is a perspective view of another exemplary heat transfer enhancement of the baseplate or the semiconductor die of the baseplate assembly of FIGS. 1 and 2, the heat transfer enhancement having porous foam;

FIG. 3D is a front view of the baseplate assembly of FIGS. 1 and 2 including elongated fins on the baseplate;

FIG. 3E is a schematic view of the baseplate assembly of FIGS. 1 and 2 including elongated fins on the baseplate;

FIG. 4 is a schematic view of a thermal management system including a baseplate assembly and flow system according to an additional aspect of the present disclosure; and

FIG. 5 is a schematic view of the baseplate assembly of FIG. 4 including elongated fins on the baseplate.

### DETAILED DESCRIPTION

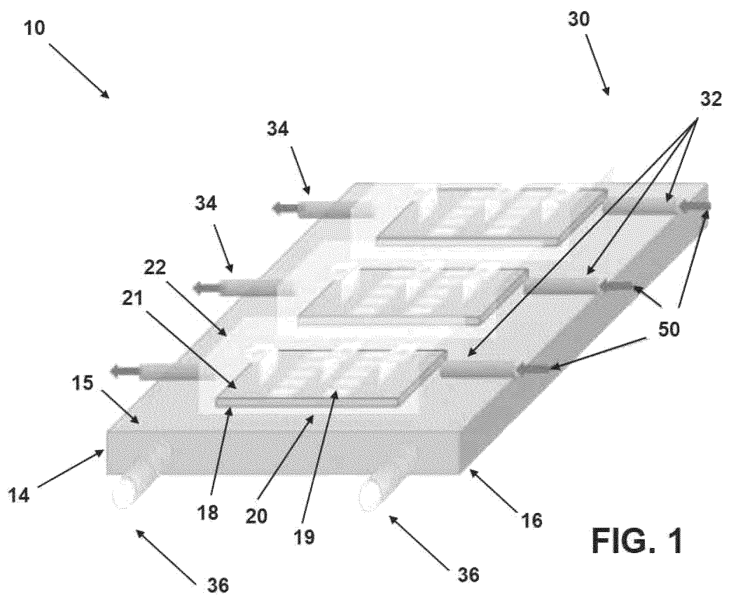

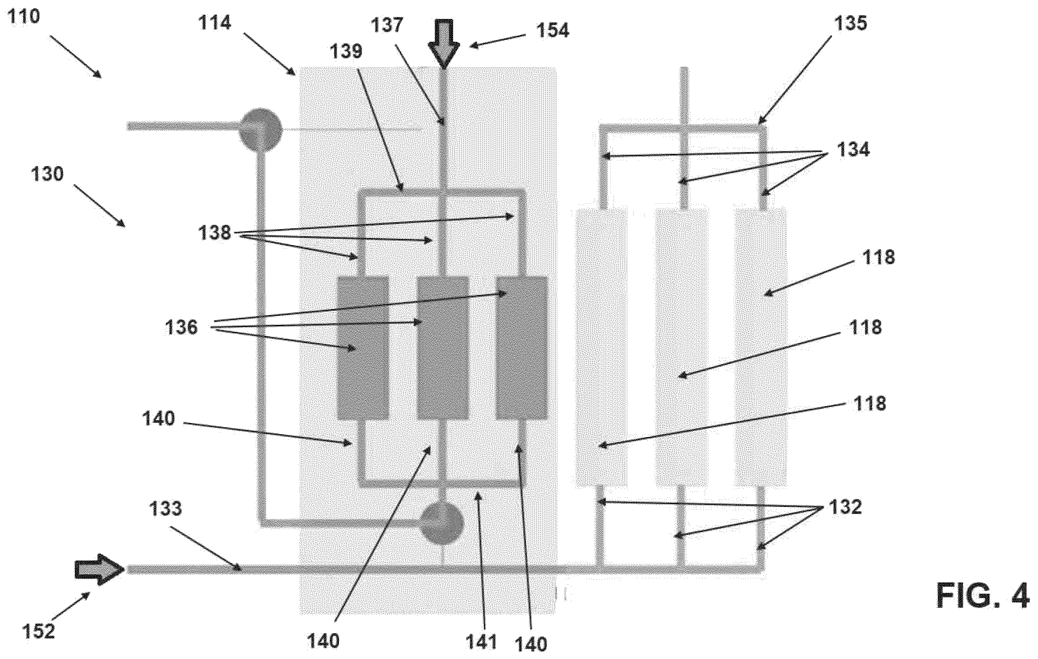

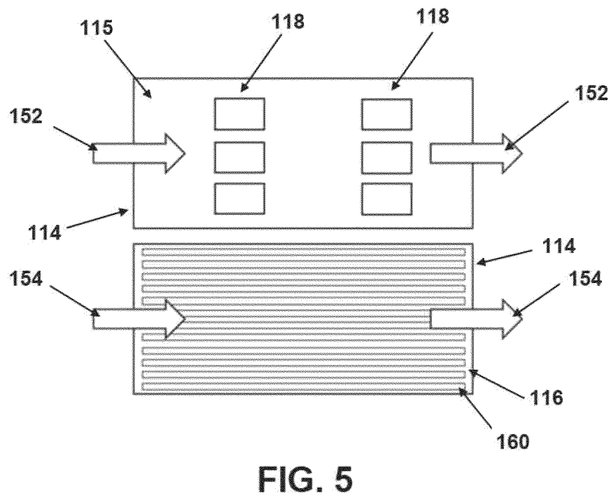

FIGS. 1-3E illustrate a thermal management system 10 according to a first aspect of the present disclosure. FIGS. 4 and 5 illustrate a thermal management system 110 according to a further aspect of the present disclosure. A thermal management system 10 includes a baseplate assembly 12 and a flow system 30. In an illustrated embodiment, the thermal management system 10 increases the heat transfer out of a semiconductor die 18 arranged on a baseplate 14 of the baseplate assembly 12 (the semiconductor die 18 may include semiconductor switches 19 arranged in power electronic modules 20 on the semiconductor die 18) via the flow system 30. The flow system 30 of the thermal management system 10 combines direct cooling of the baseplate 14 with direct cooling of the semiconductor die 18.

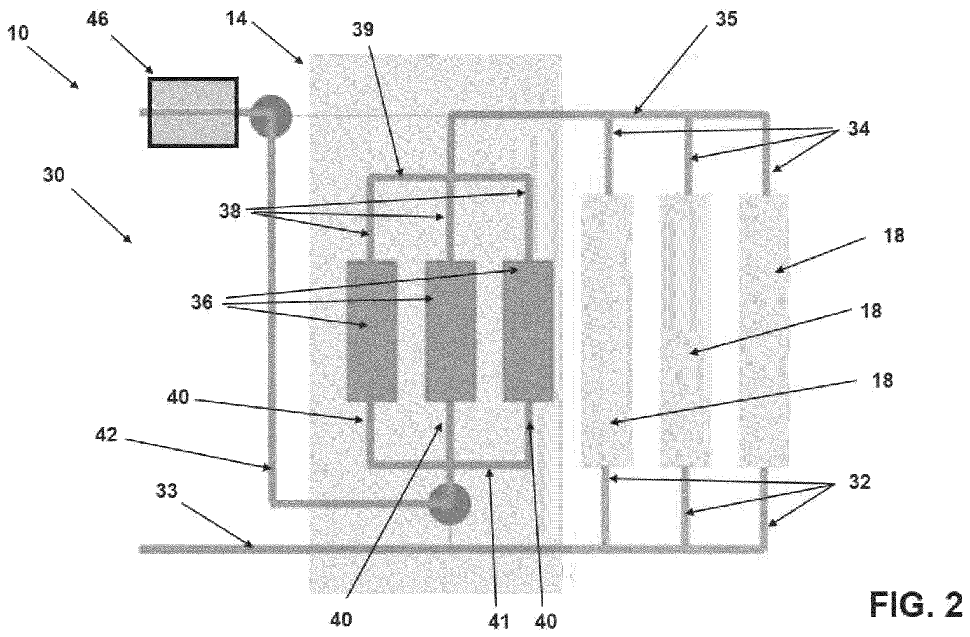

As can be seen in FIGS. 1 and 2, the thermal management system 10 includes the baseplate assembly 12 and the flow system 30. The flow system 30 directs fluid 50 onto, over, or across the semiconductor die 18 to cool the semiconductor die 18 and also to the baseplate 14 to cool the baseplate 14. Illustratively, the baseplate 14 may be a low thermal impedance baseplate 14. A low thermal impedance baseplate 14 is combined with direct semiconductor die 18 cooling to increase overall device heat rejection. The baseplate 14 may be formed from any material and shape known to a person skilled in the art, such as, for example but not limited to, cooper, aluminum, or similar base material, and may include a coating such as silver, gold, nickel, chromium, or similar coating materials.

A low thermal impedance baseplate 14 has an absence of thermal interface material required to couple the power electronic baseplate 14 to a cooling fluid. Comparative systems for thermal management use a thermal interface material in order to couple the baseplate 14 to a cooling apparatus, resulting in increased thermal resistance between cooling fluid and the die junctions arranged on the baseplate 14 (i.e. semiconductor die 18). As will be described below, surface area enhancements can be directly machined into the baseplate 14, such as the baseplate cooling channels 36 described below and shown in FIG. 2. The thermal interface materials and associated thermal resistance of conventional systems are eliminated, resulting in improved heat transfer performance. The baseplate 14 is configured to interface directly with the fluid 50 in order to reject heat out of the power electronic system (i.e. the combination of the baseplate 14 and the semiconductor die 18).

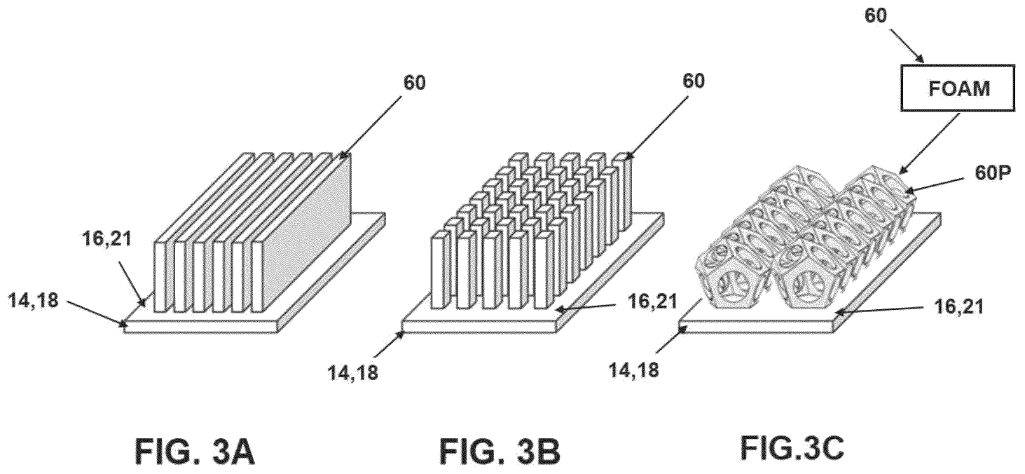

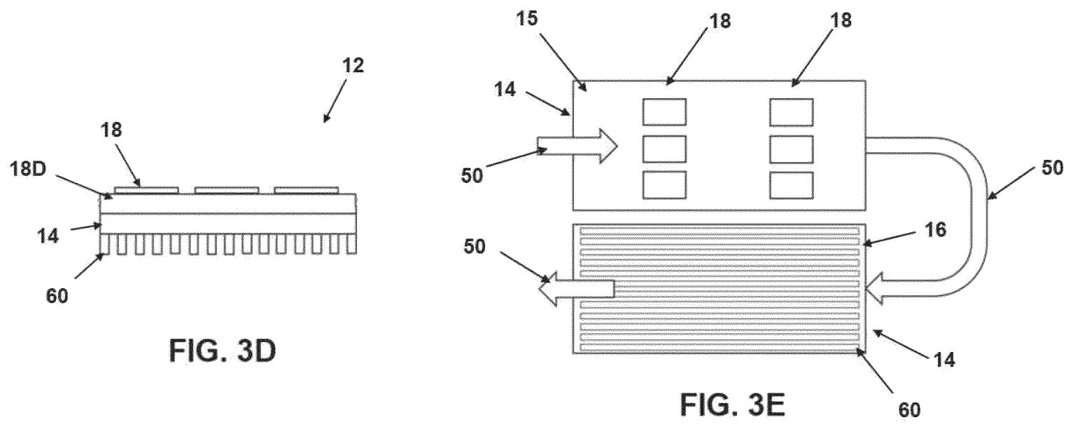

As shown in FIG. 1, the baseplate 14 defines an upper surface 15 on which the semiconductor die 18 is arranged. Illustratively, a direct bonded copper (DBC) layer 18D is formed on top of the upper surface 15 and the semiconductor dies 18 are arranged on the DBC layer 18D, as shown in FIG. 3D. The DBC layer 18D is a structure that serves to provide an electrically conductive pathway, voltage isolation, and a thermal conductive pathway to the baseplate 14, which provides the heat transfer pathway out of the device. In some embodiments, the DBC layer 18D and the baseplate 14 itself can be collectively referred to as a “baseplate”, although a person skilled in the art will understand that multiple layers, such as the baseplate 14 and DBC layer 18D of FIG. 3D, may be included in such a “baseplate”.

In one illustrated embodiment, one baseplate 14 may include multiple semiconductor dies 18 arranged thereon, as shown in FIG. 1. Although three dies 18 are shown arranged in a column in FIG. 1, any number of dies configured in any appropriate pattern may be arranged on the baseplate 14. The semiconductor die 18 defines an upper surface 21 including the switches 19 and/or power modules 20 described above. In some embodiments, the entire semiconductor die 18 may be housed in a hermetically sealed enclosure 22. In some embodiments, the semiconductor die 18 may be a field effect transistor die (“FET”).

Illustratively, the flow system 30 directs the fluid 50 onto the electrical components of the semiconductor die 18 for direct cooling, and subsequently to and through the low thermal impedance baseplate 14, as shown in FIGS. 1 and 2. In some embodiments, the fluid 50 may be a dielectric refrigerant, although fluids with other properties may be utilized as would be known to a person skilled in the art. To avoid device failure and device contamination, the flow system 30 can use a dielectric fluid capable of providing appropriate standoff voltage to avoid device failures due to arcing and short circuits, while also being non-corrosive to avoid dissolving and degraded device structure and life. By way of a non-limiting example, the dielectric fluid 50 can be tetrafluoroethane, also referred to as R134a, available from Linde, Inc. Another non-limiting example of a dielectric fluid includes Honeywell Solstice® zd refrigerant, also referred to as R1233zd, available from Honeywell Belgium N.V.

Illustratively, the flow system 30 may include a surface inlet channel 32 that directs fluid onto, across, or over the semiconductor die 18 and a surface outlet channel 34 that receives or removes the fluid therefrom and directs it to the baseplate 14. In embodiments in which a sealed enclosure 22 houses the semiconductor die 18, as shown in FIG. 1, the enclosure 22 may include openings through which the surface inlet and outlet channels 32, 34 open into the enclosure 22. The surface inlet and outlet channels 32, 34 may be tubes, pipes, or any similar fluid passageway structure known to a person skilled in the art.

As shown in FIG. 2, the surface outlet channel 34 of the flow system 30 extends to the baseplate 14 so as to pass the fluid 50 from the semiconductor die 18 to the baseplate 14. In embodiments in which multiple dies 18 are utilized on the baseplate 14, the surface outlet channel 34 of each semiconductor die 18 may extend to a common surface outlet channel 35, which then subsequently extends to the baseplate 14, as shown in FIG. 2. Similarly, in such embodiments, a common surface supply channel 33 may be utilized which supplies the fluid 50 to the system 30 and to which each surface inlet channel 32 extends from. A pump or other known means may be utilized to pump the fluid 50 into the inlet channel 33 and subsequently to the surface inlet channels 32.

The baseplate 14 may include a single baseplate cooling channel 36, or multiple cooling channels 36 as shown in FIG. 2. The baseplate cooling channel 36 includes a baseplate inlet channel 38 and a baseplate outlet channel 40. In some embodiments, the baseplate cooling channel 36 can be machined directly into a bottom surface 16 of the baseplate 14, and can either be an open-top channel or can be closed and run through the body of the baseplate 14 (i.e. a microchannel), as shown in FIG. 1. In some embodiments, a heat transfer enhancement 60 can be coupled to or formed on the baseplate 14 to improve heat transfer to the fluid 50, as shown in FIGS. 3A-3E and described in detail below.

In embodiments in which multiple baseplate cooling channels 36 are utilized, the common surface outlet channel 35 connects to a common baseplate inlet channel 39 that is connected to each baseplate inlet channel 38, and each baseplate outlet channel 40 connects to a common baseplate outlet channel 41, as shown in FIG. 2. The common baseplate outlet channel 41 may connect to a system outlet channel 42 that directs the fluid 50 away from the baseplate 14. In some embodiments, the fluid 50 can be returned to the surface inlet channel 32 or common surface supply channel 33 from the system outlet channel 42 and recirculated through the flow system 30.

In some embodiments, the flow of the fluid 50 from the surface inlet channel 32, over the semiconductor die 18, and to the surface outlet channel 34 may be referred to as a “first flow path” of the flow system 30. Similarly, the flow of the fluid 50 from the baseplate inlet channel 38, through the baseplate cooling channel 36, and to the baseplate outlet channel 40 may be referred to as a “second flow path” of the flow system 30. Together, the first and second flow paths being connected to each other via the flow of the fluid 50 from the surface inlet channel 32, over the semiconductor die 18, to the surface outlet channel 34, to the baseplate inlet channel 38, through the baseplate cooling channel 36, and to the baseplate outlet channel 40 may be referred to as a “single continuous flow path” of the flow system 30.

The convective heat transfer mode may be realized through several potential operational modes of the flow system 30. In a first operational mode, which may also be referred to as a “static fluid mode”, the fluid 50 is directed to the semiconductor die 18 via the surface inlet channel 32 and is subsequently allowed to rest statically on the upper surface 21 of the semiconductor die 18. As a result of the fluid 50 resting in place, boiling of the fluid 50 occurs at the upper surface 21 of the semiconductor die 18, which may be referred to as “pool boiling”. The pool boiling on the upper surface 21 will remove heat from the semiconductor die 18. The flow system 30 may be configured to allow the fluid 50 to boil on the semiconductor die 18 for a predetermined period of time and then can be removed from the semiconductor die 18 via a method known to a person skilled in the art, such as pumped away from the die 18 and through the surface outlet channel 34. A pump or similar mechanism may be arranged downstream of the surface outlet channel 34 to remove the fluid 50 from the die 18. Heat can then be removed from the fluid 50 through another transport medium downstream of the semiconductor die 18, such as a heat exchanger 46 arranged downstream of the baseplate 14, as shown in FIG. 2.

In a second operational mode, fluid 50 is directed to the semiconductor die 18 from the surface inlet channel 32 and flows unimpeded across the upper surface 21, thus cooling the semiconductor die 18 as the fluid 50 flows across the surface 21 and to the surface outlet channel 34.

In a third operational mode, the fluid 50 flows across the semiconductor die 18 via a heat transfer enhancement 60 coupled to or formed on the semiconductor die 18, as shown in FIGS. 3A-3E. The heat transfer enhancement 60 can be formed on one of the baseplate 14 and the semiconductor die 18, or both, and as such, the description of the heat transfer enhancement 60 below applies to both the baseplate 14 and the semiconductor die 18.

The heat transfer enhancement 60 may include, but is not limited to, a microchannel, such as the baseplate cooling channel 36 formed in the interior of the baseplate 14, as shown in FIG. 1. A microchannel or microchannels can extend through the semiconductor die 18 similar to the baseplate cooling channel 36 formed in the interior of the baseplate 14 shown in FIG. 1. In some embodiments, the heat transfer enhancement 60 may include a pin fin array including either elongated fins, as shown in FIG. 3A, or narrow pins, as shown in FIG. 3B. In some embodiments, the heat transfer enhancement 60 may include porous foam including individual pores 60P that allow fluid 50 to pass therethrough, as shown in FIG. 3C.

FIGS. 3D and 3E show an exemplary baseplate assembly 12 setup, including six semiconductor dies 18 arranged on the upper surface 15 of the baseplate 14. Illustratively, the direct bonded copper (DBC) layer 18D is formed on top of the upper surface 15 and the semiconductor dies 18 are arranged on the DBC layer 18D. As can be seen in FIGS. 3D and 3E, the baseplate 14 includes a heat transfer enhancement 60 formed as elongated fins, while the semiconductor dies 18 do not include a heat transfer enhancement 60, allowing the fluid 50 to simply flow over the dies 18. In other embodiments, the semiconductor dies 18, as well as the baseplate 14, can include any combination of the heat transfer enhancements 60 described above.

In operation, a continuous supply of fluid 50 is fed transversely across the semiconductor die 18, in one of the exemplary operational modes described above, in order to remove heat from the semiconductor die 18. The fluid 50 can be provided to the flow system 30 in any manner that would be understood by a person skilled in the art. By way of non-limiting examples, the fluid 50 can be provided to the common surface supply channel 33 or the surface inlet channel 32 via active pumping, passive movement enabled by a change in density occurring in the heat transfer process, or passive heat transfer mechanisms such as heat pipes, oscillating heat pipes, vapor chambers, and thermosyphons.

A study was conducted in order to consider heat transfer feasibility of the thermal management system 10 described herein. In the thermal management system 10 described above, the heat transfer rate is given by Equation 1, where T_{FET} is a temperature of a field effect transistor (FET) associated with the semiconductor die 18, and T_{REF} is a reference temperature:

Q=hA(T_{FET}−T_{REF}) (1)

In at least one embodiment, h is equal to 2.0 kW/m²K, A is equal to 1.46e−4 m², T_{FET} is equal to 150 degrees Celsius, and T_{REF} is equal to 25 degrees Celsius. This results in a Q value of 36.5 W. A single FET for the above surface area of the semiconductor die 18 generates approximately 321 W of heat, representing around 11% of the total heat generation over baseplate only cooling. This assumes the only heat transfer out of the top-side cooling occurs at the surface area of the FET, and that the heat transfer coefficient of 2 kW/m²K is appropriate. In a flow-boiling condition, heat transfer coefficients can exceed 2 kW/m²K, and it is highly likely that other surface area in contact with the heat transfer fluid would convect heat away (although it is likely that the remaining surface area would be at a much lower temperature than the 150 degree Celsius FET temperature).

By way of a non-limiting example, the embodiment described above can represent a lower bound. In some embodiments, an upper bound of the above equation can include variable values of h equaling 10 kW/m²K, A equaling 0.003726 m², T_{FET} equaling 150 degrees Celsius, and T_{REF} equaling 25 degrees Celsius. This results in a Q value of 4.66 kW. The upper bound assumes a higher heat transfer coefficient resulting from flow boiling in the fluid 50 and the entire footprint of the module participating in the heat transfer process, at the same temperature. A single unit of that footprint includes four FETS for a total of 1.28 kW heat loss. As such, 4.66 kW exceeds 1.28 kW, and the actual operating point would be with the entire surface at 66.5 degrees Celsius (resulting in T_{FET} equaling 66.5 degrees Celsius and thus Q equaling 1.28 kW when h equals 10, A equals 0.003726, and T_{REF} equals 25 degrees Celsius).

In some embodiments, an intermediate solution between the upper and lower embodiments described above can consider the FETs at 150 degrees Celsius with a higher heat transfer coefficient, but the remaining surface area at 100 degrees Celsius and lower heat transfer coefficient. For example, a calculation to determine this heat transfer rate (Q) can be (Q=10*(1.46e−4*4)*(150-25)+2*(0.003725-4*1.46e−4)*(100-25)=1.2 kW). The intermediate solution embodiment suggests that 94% of the total heat generation could be addressed using the direct die cooling approach described herein, which indicates that, when combined with the baseplate also described herein, provides substantial power density improvements.

Another embodiment of a flow system 130 of a thermal management system 110 in accordance with the present disclosure is shown in FIG. 4. The flow system 130 and thermal management system 110 are substantially similar to the flow system 30 and thermal management system 10 shown in FIGS. 1-3B and described above. Accordingly, similar reference numbers in the 100 series indicate features that are common between the thermal management system 110 and the thermal management system 10. The description of the thermal management system 10, and in particular the flow system 30, are incorporated by reference to apply to the thermal management system 110 and the flow system 130, except in instances when they conflict with the specific description and the drawings of the thermal management system 110 and the flow system 130.

Similar to the flow system 30 described above, the flow system 130 directs fluid to the semiconductor die 118 and to the baseplate 114. Unlike the flow system 30, the flow system 130 utilizes a first fluid 152 and a second fluid 154. The first fluid 152 is directed onto the components of the semiconductor die 18 for direct cooling. The second fluid 154 is separate from the first fluid 152 and is directed through the low thermal impedance baseplate 114. This is accomplished by the surface outlet channels 134 not being fluidically connected to the baseplate inlet channels 138. Instead, a separate supply of fluid, in particular a supply of the second fluid 154, is fluidically connected to the baseplate inlet channels 138 via a second supply channel 137. The first fluid 152 is provided to the surface inlet channels 132 via the common surface supply channel 133.

The fluids 152, 154 can include the same types of fluid described above with reference to the fluid 50, in particular those including the same dielectric and cooling properties. In some embodiments, the second fluid 154 is different from the first fluid 152. In other embodiments, the first and second fluid 152, 154 are the same type of fluid.

In some embodiments, the flow of the fluid 152 from the surface inlet channel 132, over the semiconductor die 118, and to the surface outlet channel 134 may be referred to as a “first flow path” of the flow system 130. Similarly, the flow of the second fluid 154 from the baseplate inlet channel 138, through the baseplate cooling channel 136, and to the baseplate outlet channel 140 may be referred to as a “second flow path” of the flow system 130. In this embodiment, the first flow path is not in fluidic communication with the second flow path.

FIG. 5 shows an exemplary baseplate assembly 112 setup, including six semiconductor dies 118 arranged on the upper surface 115 of the baseplate 114. The baseplate 114 includes a heat transfer enhancement 160 formed as elongated fins, while the semiconductor dies 118 do not include a heat transfer enhancement 160 (i.e. the heat transfer enhancements 60 described above), allowing the first fluid 152 to simply flow over the dies 118. The second fluid 154 flows through the channels created by the elongated fins of the heat transfer enhancement 160. In other embodiments, the semiconductor dies 118, as well as the baseplate 114, can include any combination of the heat transfer enhancements 60, 160 described above.

According to a further aspect of the present disclosure, a method includes providing a baseplate assembly 12 including a baseplate 14 defining an upper baseplate surface 15 and a semiconductor die 18 defining an upper semiconductor surface 21, arranging the semiconductor die 18 on the baseplate 14 such that the upper semiconductor surface 21 is spaced apart from the upper baseplate surface 15, providing a flow system 30 including a first flow path extending over and in thermal contact with the semiconductor die 18 and a second flow path in thermal contact with the baseplate 14, the flow system 30 including a fluid 50 flowing through the first flow path and the second flow path, and directing the fluid 50 over the semiconductor die 18 via the first flow path and to the baseplate 14 via the second flow path so as to transfer heat away from the semiconductor die 18 and from the baseplate 14 so as to cool the baseplate assembly 12.

The thermal management system 10, 110 described herein advantageously provides increased overall system power density as a result of the high heat flux rejection capability. The disclosed thermal management system 10, 110 leverages baseplate 14, 114 cooling strategy where conventional thermal interface materials are eliminated, thus providing a low thermal impedance path between coolant fluid and the semiconductor die 18, 118 junction and associated heat generation source(s), thus improving cooling capacity as well as current capacity of the system 10, 110.

The disclosed thermal management system 10, 110 further provides for utilization of direct dielectric cooling via the flow system 30, 130 described herein to both protect the power electronic devices and provide enhanced heat transfer capability from a combination of isothermal temperature operation under heating and enhanced convection coefficients in the isothermal region. The disclosed system 10, 110 further provides for utilization of the flow system 30, 130 to regulate the degree of sub-cooling deployed to the baseplate 14, 114 cooling structure.

Persons of skill in the art will understand that advancements in electronic systems are pushing shipboard power distribution systems to higher voltage, more power dense solutions. Moreover, it is desirable to reduce cost, increase flexibility, provide rapid scalability, extend life, and lower maintenance. These objectives are in conflict, as increased power density reduces life due to thermal stress on the components. In addition, increased use of renewable energy and the associated transmission and storage, along with growth in the electric vehicle space, suggest development towards higher power density solutions. A limiting factor in power density related to semiconductor power switch devices is the junction temperature of the semiconductor devices. Therefore, in order to expand the operating range of such devices, techniques to lower the junction temperature and improve efficiency at a given operating point would be advantageous. Thermal management solutions that increase heat transfer out of the device serve such purposes and therefore would be advantageous.

The present disclosure relates to a low thermal impedance baseplate as an important attribute of the technology. For purposes of this disclosure, a low thermal impedance baseplate is defined as a being a traditional baseplate with heat transfer surface enhancements, such as fins, machined directly into the baseplate structure. The cooling fluid is allowed to contact directly with the baseplate structure resulting in a lower of overall thermal impedance between the cooling fluid and semiconductor junction. This compares to traditional power modules whose baseplates require coupling using high impedance thermal interface materials mounted to heat sink housing.

The present disclosure also relates to direct semiconductor die cooling as an important attribute of the technology. For purposes of this disclosure, direct semiconductor die cooling is defined as exposing the top sides of the semiconductor die directly to the cooling fluid. Semiconductor die are traditionally encapsulated within an insulating and dielectric silicone gel and then enclosed within the power module housing eliminating any heat transfer pathway out of the top die surface. Exposing the surface directly to the cooling fluid allows for improved heat transfer.

It is to be understood that while the invention has been described in this document with respect to a specific but illustrative embodiment, various configurational and size changes may be made within the scope of the invention described and claimed herein. The drawings, although not fully dimensioned, are to scale.

1. A thermal management system, comprising:
a baseplate assembly including a baseplate defining an upper baseplate surface and a semiconductor die defining an upper semiconductor surface, the semiconductor die being arranged on the baseplate such that the upper semiconductor surface is spaced apart from the upper baseplate surface; and
a flow system including a first flow path extending over and in thermal contact with the semiconductor die and a second flow path in thermal contact with the baseplate, the flow system including a fluid flowing through the first flow path and the second flow path,
wherein the flow system is configured to direct the fluid over the semiconductor die via the first flow path and to the baseplate via the second flow path so as to transfer heat away from the semiconductor die and from the baseplate so as to cool the baseplate assembly.

2. The thermal management system of claim 1, wherein the first flow path is defined by at least one surface inlet channel that directs the fluid onto the semiconductor die and at least one surface outlet channel that receives the fluid from the semiconductor die and directs the fluid away from the semiconductor die.

3. The thermal management system of claim 2, wherein the second flow path is defined by at least one baseplate inlet channel that directs the fluid into thermal contact with the baseplate, at least one baseplate cooling channel that directs the fluid over or through the baseplate, and at least one baseplate outlet channel that receives the fluid from the at least one baseplates cooling channel and directs the fluid away from the baseplate.

4. The thermal management system of claim 3, wherein the flow system further includes a common surface outlet channel fluidically connected to the at least one surface outlet channel and to the at least one baseplate inlet channel such that the fluid is configured to flow from the at least one surface outlet channel to the at least one baseplate inlet channel so as to define a single continuous flow path from the first flow path to the second flow path.

5. The thermal management system of claim 4, wherein the flow system is configured to control a flow of the fluid over the semiconductor die such that, in a first operational mode, the fluid flows continuously and unimpeded over the upper semiconductor surface.

6. The thermal management system of claim 4, wherein the flow system is configured to control a flow of the fluid over the semiconductor die such that, in a second operational mode, the fluid is directed onto the upper semiconductor surface and then remains on the upper semiconductor surface for a predetermined period of time such that the fluid boils.

7. The thermal management system of claim 4, wherein the flow system further includes at least one heat transfer enhancement arranged on the upper semiconductor surface, wherein the at least one heat transfer enhancement includes at least one of microchannels, a porous foam material, or a pin fin array, and wherein the at least one surface inlet channel directs the fluid through the at least one heat transfer enhancement.

8. The thermal management system of claim 1, wherein the baseplate is a low thermal impedance baseplate and the fluid is a dielectric refrigerant.

9. The thermal management system of claim 1, wherein the semiconductor die is a field effect transistor die and is directly exposed to the fluid.

10. The thermal management system of claim 1, wherein the fluid is a hydrofluorocarbon refrigerant.

11. The thermal management system of claim 3, wherein the fluid includes a first fluid and a second fluid, wherein the flow system further includes a surface inlet supply channel configured to supply the first fluid to the first flow path and a baseplate inlet supply channel configured to supply the second fluid to the second flow path, and wherein the first flow path is not in fluidic communication with the second flow path.

12. The thermal management system of claim 11, wherein the first fluid is different than the second fluid.

13. A thermal management system, comprising:
a baseplate assembly including a baseplate and a semiconductor die; and
a flow system in thermal contact with the baseplate and the semiconductor die and including a fluid configured to flow through the flow system,
wherein the flow system is configured to direct the fluid over the semiconductor die and to the baseplate so as to transfer heat away from the semiconductor die and from the baseplate so as to cool the baseplate assembly.

14. The thermal management system of claim 13, wherein the baseplate is a low thermal impedance baseplate.

15. The thermal management system of claim 13, wherein the fluid is a dielectric refrigerant.

16. The thermal management system of claim 14, wherein the flow system includes a single continuous flow path that extends over and is in thermal contact with the semiconductor die and that is in thermal contact with the low thermal impedance baseplate.

17. The thermal management system of claim 14, wherein the flow system has at least two flow paths, the at least two flow paths including a first flow path that extends over and is in thermal contact with the semiconductor die and a second flow path that is in thermal contact with the low thermal impedance baseplate.

18. The thermal management system of claim 17, wherein the fluid includes a first fluid flowing through the first flow path and a second fluid flowing through the second flow path, and wherein the first fluid is different than the second fluid.

19. A method, comprising:
providing a baseplate assembly including a baseplate defining an upper baseplate surface and a semiconductor die defining an upper semiconductor surface;
arranging the semiconductor die on the baseplate such that the upper semiconductor surface is spaced apart from the upper baseplate surface;
providing a flow system including a first flow path extending over and in thermal contact with the semiconductor die and a second flow path in thermal contact with the baseplate, the flow system including a fluid flowing through the first flow path and the second flow path; and
directing the fluid over the semiconductor die via the first flow path and to the baseplate via the second flow path so as to transfer heat away from the semiconductor die and from the baseplate so as to cool the baseplate assembly.

20. The method of claim 19, wherein the first flow path is defined by at least one surface inlet channel that directs the fluid onto the semiconductor die and at least one surface outlet channel that receives the fluid from the semiconductor die and directs the fluid away from the semiconductor die, wherein the second flow path is defined by at least one baseplate inlet channel that directs the fluid into thermal contact with the baseplate, at least one baseplate cooling channel that directs the fluid over or through the baseplate, and at least one baseplate outlet channel that receives the fluid from the at least one baseplates cooling channel and directs the fluid away from the baseplate, and wherein the flow system further includes a common surface outlet channel fluidically connected to the at least one surface outlet channel and to the at least one baseplate inlet channel such that the fluid is configured to flow from the at least one surface outlet channel to the at least one baseplate inlet channel so as to define a single continuous flow path from the first flow path to the second flow path.
